(19) United States
(12) Patent Application Publication
(10) Pub. No.: US 2022/0320685 A1
(43) Pub. Date: Oct. 6, 2022

(54) ELECTRICAL CONNECTION ASSEMBLY AND BATTERY PACK SIGNAL ACQUISITION DEVICE

(71) Applicant: Tyco Electronics (Shanghai) Co. Ltd., Shanghai (CN)

(72) Inventors: Bingjing (Crystal) XUE, SHANGHAI (CN); Xiao (Nichee) ZHOU, SHANGHAI (CN); Ziwei (Vivi) LI, SHANGHAI (CN)

(73) Assignee: Tyco Electronics (Shanghai) Co. Ltd., Shanghai (CN)

(21) Appl. No.: 17/705,476

(22) Filed: Mar. 28, 2022

(30) Foreign Application Priority Data
Apr. 2, 2021 (CN) 202110363398.5

(51) Int. Cl. H01M 50/503; H01M 50/204; H01M 10/42; H05K 1/18

(52) U.S. Cl. CPC H01M 50/503; H01M 50/204; H01M 10/425; H05K 1/189

(57) ABSTRACT

The present invention discloses an electrical connection assembly and a battery pack signal acquisition device. The battery pack signal acquisition device has: a signal transmission bus; and an electrical connection assembly for electrically connecting a battery cell to the signal transmission bus to collect an electrical parameter of the battery cell. The electrical connection assembly and the signal transmission bus are respectively formed and electrically connected with each other. In the present invention, the electrical connection assembly can be replaced separately without replacing the signal transmission bus, which improves the convenience of use and reduces the later maintenance cost.

### CROSS-REFERENCE TO RELATED APPLICATION

This application claims the benefit of Chinese Patent Application No. 202110363398.5 filed on Apr. 2, 2021 in the State Intellectual Property Office of China, the whole disclosure of which is incorporated herein by reference.

### BACKGROUND OF THE INVENTION

### Field of the Invention

The present invention relates to an electrical connection assembly and a battery pack signal acquisition device comprising the electrical connection assembly.

### Description of the Related Art

Battery pack is the most important part of electric vehicle. In the prior art, in order to ensure the service life of the battery pack, the temperature and voltage of the battery pack must be collected and controlled to ensure that the temperature and voltage of the battery pack remain stable.

In the prior art, the signal acquisition device for collecting the temperature and voltage of the battery pack usually includes a flexible printed circuit board (FPC) and a fuse and a temperature sensor welded on the flexible printed circuit board. The disadvantage of the existing signal acquisition device is that the fuse, temperature sensor and other devices cannot be replaced separately. During maintenance, the whole flexible printed circuit board must be replaced. The maintenance cost is very high and the use is very inconvenient.

In addition, in the prior art, components such as fuses and temperature sensors are welded to the flexible printed circuit board by means of reflow welding, tin welding, ultrasonic welding or laser welding. Therefore, the flexible printed circuit board must be covered with a high-temperature resistant protective film to prevent the high temperature generated during welding from adversely affecting the flexible printed circuit board, which greatly increases the manufacturing cost.

### SUMMARY OF THE INVENTION

The present invention has been made to overcome or alleviate at least one aspect of the above mentioned disadvantages.

According to an aspect of the present invention, there is provided a battery pack signal acquisition device comprising: a signal transmission bus; and an electrical connection assembly for electrically connecting a battery cell to the signal transmission bus to collect an electrical parameter of the battery cell, the electrical connection assembly and the signal transmission bus are respectively formed and electrically connected with each other.

According to an exemplary embodiment of the present invention, the battery pack signal acquisition device further comprises an electrical adapter electrically connected with the electrical connection assembly and the signal transmission bus respectively.

According to another exemplary embodiment of the present invention, the electrical adapter comprises a pair of connection terminals adapted to mated with each other, the pair of connection terminals are electrically connected with the electrical connection assembly and the signal transmission bus respectively, so that the electrical connection assembly and the signal transmission bus are detachably connected.

According to another exemplary embodiment of the present invention, the electrical adapter comprises a first connection terminal which is crimped to the signal transmission bus to electrically connect the electrical connection assembly to the signal transmission bus.

According to another exemplary embodiment of the present invention, the first connection terminal is crimped to the signal transmission bus by puncture crimping.

According to another exemplary embodiment of the present invention, the first connection terminal is crimped to the electrical connection assembly by puncture crimping to realize an electrical connection between the first connection terminal and the electrical connection assembly.

According to another exemplary embodiment of the present invention, the first connection terminal comprises a body extending along a straight line, a first wing is formed on each side of one end of the body, and a second wing is formed on each side of the other end of the body; the first wing and the second wing are symmetrically arranged at both ends of the body, so that the first wing and the second wing are interchangeable in use without distinction.

According to another exemplary embodiment of the present invention, the first connection terminal comprises a first body and a second body, one end of the second body is vertically connected to the middle part of the first body, so that the first connection terminal is in a T-shape.

According to another exemplary embodiment of the present invention, the first connection terminal comprises a first body and a second body, one end of the second body is vertically connected to one end of the first body, so that the first connection terminal is in an L-shape.

According to another exemplary embodiment of the present invention, the electrical connection assembly further includes an electrical connector, one end of the electrical connector is electrically connected with the signal transmission bus, and the other end is electrically connected to the battery cell.

According to another exemplary embodiment of the present invention, the electrical connector is a flexible electrical connector and comprises a flexible film carrier and a conductive trace integrated on the flexible film carrier.

According to another exemplary embodiment of the present invention, the electrical connector further includes a fuse integrated on the flexible film carrier and electrically connected with the conductive trace.

According to another exemplary embodiment of the present invention, the fuse includes a surface mount fuse adapted to be mounted on the flexible film carrier in a surface mount manner and/or a conductive trace fuse formed on the flexible film carrier in the form of a conductive trace.

According to another exemplary embodiment of the present invention, the electrical connector is a flexible flat cable, a flexible printed circuit board or a flexible wire.

According to another exemplary embodiment of the present invention, the battery pack signal acquisition device comprises a plurality of electrical connectors arranged at an end and a side of the signal transmission bus, the electrical connector arranged at the side of the signal transmission bus is bent in a non-linear shape, and the electrical connector arranged at the end of the signal transmission bus is not bent.

According to another exemplary embodiment of the present invention, the electrical connection assembly further includes a second connection terminal, one end of the second connection terminal is connected to the electrical connector, and the other end is electrically connected to the battery cell.

According to another exemplary embodiment of the present invention, the electrical connection assembly further includes a welding terminal to be welded to the battery cell, and the other end of the second connection terminal is connected with the welding terminal.

According to another exemplary embodiment of the present invention, the electrical connection assembly further includes a temperature sensor assembly for detecting the temperature of the battery cell, and the temperature sensor assembly is electrically connected with the second connection terminal.

According to another exemplary embodiment of the present invention, the battery pack signal acquisition device further comprises a bracket on which the signal transmission bus and the electrical connection assembly are installed.

According to another aspect of the present invention, there is provided an electrical connection assembly for electrically connecting a battery cell to a signal transmission bus; the electrical connection assembly comprises an electrical connector and a first connection terminal, one end of the first connection terminal is electrically connected with the electrical connector; the other end of the first connection terminal is adapted to be connected to a signal transmission bus to electrically connect the electrical connection assembly to the signal transmission bus.

According to an exemplary embodiment of the present invention, the electrical connection assembly further comprises a second connection terminal, one end of the second connection terminal is connected to the electrical connector, and the other end is electrically connected to the battery cell to collect an electrical signal of the battery cell.

In the some of the above exemplary embodiments according to the present invention, the electrical connection assembly is electrically connected to the signal transmission bus by terminal crimping. Therefore, the electrical connection assembly can be replaced separately without replacing the signal transmission bus, which improves the convenience of use and reduces the later maintenance cost.

In addition, in some of the above exemplary embodiments of the present invention, the electrical connection assembly is electrically connected to the signal transmission bus by terminal crimping instead of tin welding, ultrasonic welding or laser welding.

Therefore, the signal transmission bus does not need to be resistant to high temperature, which reduces the production cost.

### BRIEF DESCRIPTION OF THE DRAWINGS

The above and other features of the present invention will become more apparent by describing in detail exemplary embodiments thereof with reference to the accompanying drawings, in which:

FIG. 1 shows an illustrative view of a battery pack signal acquisition device according to an exemplary embodiment of the present invention;

FIG. 2 shows an illustrative view of an electrical connection assembly in the battery pack signal acquisition device shown in FIG. 1;

FIG. 3 shows an illustrative exploded view of the electrical connection assembly shown in FIG. 2;

FIG. 4 shows an illustrative view of an electrical connection assembly of a battery pack signal acquisition device according to another exemplary embodiment of the present invention;

FIG. 5 shows an illustrative perspective view of a first connection terminal of the electrical connection assembly shown in FIG. 4;

FIG. 6 shows an illustrative perspective view of a first connection terminal according to another exemplary embodiment of the present invention; and

FIG. 7 shows an illustrative view of an electrical connection assembly according to another exemplary embodiment of the present invention.

### DETAILED DESCRIPTION OF PREFERRED EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to a general concept of the present invention, there is provided a battery pack signal acquisition device comprising: a signal transmission bus; and an electrical connection assembly for electrically connecting a battery cell to the signal transmission bus to collect an electrical parameter of the battery cell, the electrical connection assembly and the signal transmission bus are respectively formed and electrically connected with each other.

According to another general concept of the present invention, there is provided an electrical connection assembly for electrically connecting a battery cell to a signal transmission bus; the electrical connection assembly comprises an electrical connector and a first connection terminal, one end of the first connection terminal is electrically connected with the electrical connector; the other end of the first connection terminal is adapted to be connected to a signal transmission bus to electrically connect the electrical connection assembly to the signal transmission bus.

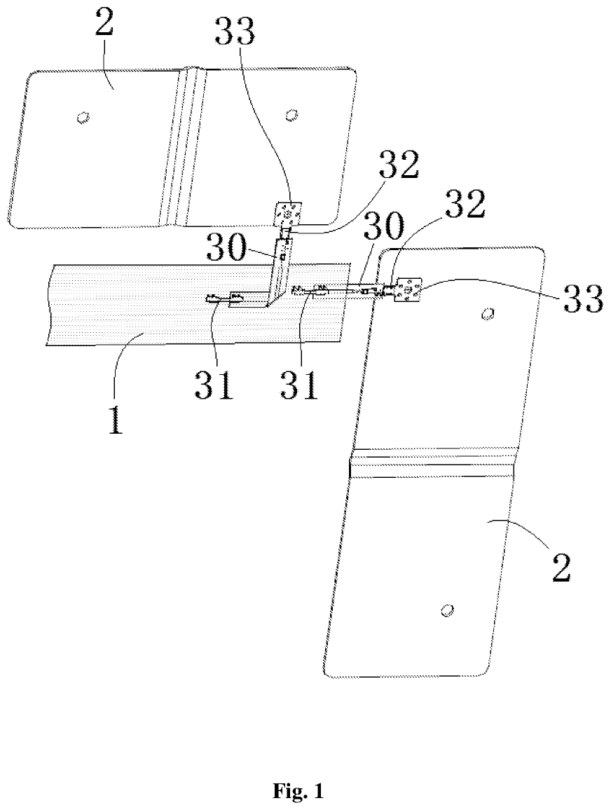

FIG. 1 shows an illustrative view of a battery pack signal acquisition device according to an exemplary embodiment of the present invention.

As shown in FIG. 1, in the illustrated embodiment, the battery pack signal acquisition device mainly includes a signal transmission bus 1 and a plurality of electrical connection assemblies 3. The plurality of electrical connection assemblies 3 are used to electrically connect a plurality of bus bars 2 of a battery pack to the signal transmission bus 1 respectively to collect electrical parameters of a battery cell, such as voltage, pressure, resistance, current or temperature signals.

As shown in FIG. 1, in the illustrated embodiment, the battery pack signal acquisition device further comprises a plurality of electrical adapters for electrically connecting the electrical connection assemblies 3 to the signal transmission bus 1 respectively. The electrical adapter may comprise a first connection terminal 31. The first connection terminal 31 is crimped to the signal transmission bus 1 to electrically connect the electrical connection assembly 3 to the signal transmission bus 1. Therefore, in the present invention, the electrical connection assembly 3 can be replaced separately without replacing the signal transmission bus 1, which improves the convenience of use and reduces the later maintenance cost. In addition, in the present invention, the electrical connection assembly 3 is electrically connected to the signal transmission bus 1 by terminal crimping instead of tin welding, ultrasonic welding or laser welding. Therefore, the signal transmission bus 1 does not need to be resistant to high temperature, which reduces the production cost.

Note that the present invention is not limited to the illustrated embodiment. For example, the electrical connection assembly 3 can also be electrically connected to the signal transmission bus 1 through rivet, special joint and any other suitable type of electrical adapter.

Although not shown, in another exemplary embodiment of the present invention, the electrical adapter may comprise a pair of connection terminals adapted to mated with each other, the pair of connection terminals are electrically connected with the electrical connection assembly 3 and the signal transmission bus 1 respectively, so that the electrical connection assembly 3 and the signal transmission bus 1 are detachably connected. In this way, the electrical connection assembly 3 can be more easily removed from the signal transmission bus 1, making the replacement of the electrical connection assembly 3 more convenient.

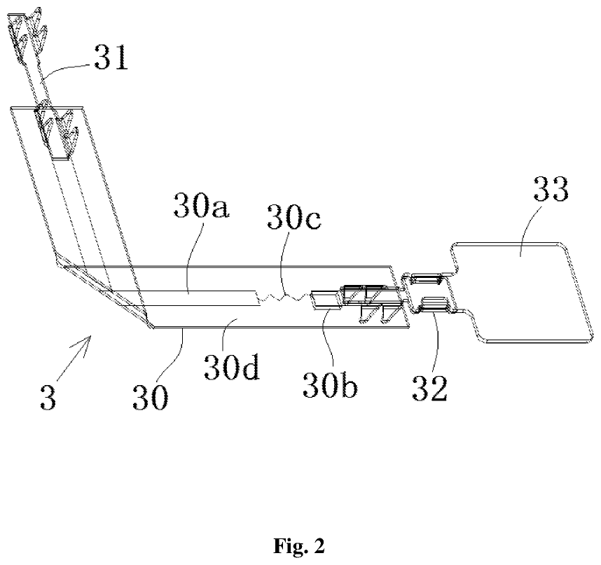

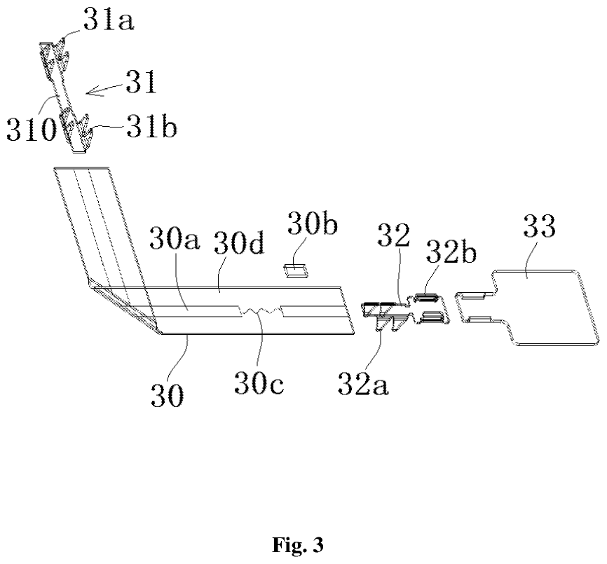

FIG. 2 shows an illustrative view of an electrical connection assembly 3 in the battery pack signal acquisition device shown in FIG. 1; FIG. 3 shows an illustrative exploded view of the electrical connection assembly 3 shown in FIG. 2.

As shown in FIGS. 1 to 3, in the illustrated embodiment, the signal transmission bus 1 may be a flexible flat cable (FFC), and the first connection terminal 31 is suitable for being crimped to the signal transmission bus 1 by puncture crimping. However, the present invention is not limited to this, and the signal transmission bus 1 may be a flexible printed circuit (FPC).

As shown in FIGS. 1 to 3, in the illustrated embodiment, the electrical connection assembly 3 also includes an electrical connector 30 located between the signal transmission bus 1 and the bus bar 2. One end of the electrical connector 30 is electrically connected with the first connection terminal 31, and the other end is electrically connected with the bus bar 2.

As shown in FIGS. 1 to 3, in the illustrated embodiment, the electrical connector 30 is a flexible electrical connector that can be bent. In an exemplary embodiment of the present invention, the electrical connector 30 includes a flexible film carrier 30d and a conductive trace 30a integrated on the flexible film carrier 30d. The conductive trace 30a may be formed on the flexible film carrier 30d by any suitable process, such as printing.

As shown in FIGS. 1 to 3, in the illustrated embodiment, the electrical connector 30 also includes fuses 30b and 30c. The fuses 30b and 30c are integrated on the flexible film carrier 30d and electrically connected with the conductive traces 30a. As shown in FIG. 2, in an exemplary embodiment of the present invention, the fuses 30b and 30c may include a surface mount fuse 30b adapted to be mounted on the flexible film carrier 30d in a surface mount manner and/or a conductive trace fuse 30c formed on the flexible film carrier 30d in the form of a conductive trace. The use of conductive trace fuse 30c can greatly reduce the manufacturing cost.

As shown in FIGS. 1 to 3, in the illustrated embodiment, the first connection terminal 31 is crimped to the electrical connector 30 by puncture crimping to realize the electrical connection between the first connection terminal 31 and the electrical connector 30.

Note that the electrical connector 30 of the present invention is not limited to the embodiments shown in FIGS. 1 to 3, and may also be a flexible flat cable, a flexible printed circuit board, or a flexible wire.

As shown in FIGS. 1 to 3, in the illustrated embodiment, the first connection terminal 31 includes a body 310 extending along a straight line. Toothed first wings 31a are respectively formed on both sides of one end of the body 310 of the first connection terminal 31. The toothed first wings 31a are suitable for being crimped to the signal transmission bus 1 by puncture crimping. Toothed second wings 31b are respectively formed on both sides of the other end of the body 310 of the first connection terminal 31, the toothed second wings 31b are suitable for being crimped to the electrical connector 30 by puncture crimping.

As shown in FIGS. 1 to 3, in the illustrated embodiment, the first wings 31a on both sides of one end of the body 310 of the first connection terminal 31 are staggered by a predetermined distance in the extension direction of the body 310, that is, the first wings 31a on one side of the body 310 are staggered from the first wings 31a on the other side of the body 310. In this way, the first wings 31a on both sides are staggered from each other after being crimped to the signal transmission bus 1, which can improve the electrical connection performance between the first connection terminal 31 and the signal transmission bus 1.

As shown in FIGS. 1 to 3, in the illustrated embodiment, the second wings 31b on both sides of the other end of the body 310 of the first connection terminal 31 are staggered by a predetermined distance in the extension direction of the body 310, that is, the second wings 31b on one side of the body 310 are staggered from the second wings 31b on the other side of the body 310. In this way, the second wings 31b on both sides are staggered from each other after being crimped to the electrical connector 30, which can improve the electrical connection performance between the first connection terminal 31 and the electrical connector 30.

As shown in FIGS. 1 to 3, in the illustrated embodiment, the first wing 31a and the second wing 31b of the first connection terminal 31 are symmetrically arranged at both ends of the body 310, so that the first wing 31a and the second wing 31b can be interchanged in use without distinction. That is, in use, either of the first wing 31a and the second wing 31b can be selected to be crimped to the signal transmission bus 1 without distinguishing and identifying the first wing 31a and the second wing 31b. This symmetrical structure is very convenient to use.

As shown in FIGS. 1 to 3, in the illustrated embodiment, due to the layout requirements of the signal transmission bus 1 and the bus bars 2, the electrical connectors 30 arranged on the side of the signal transmission bus 1 needs to be bent by 90 degrees, and the electrical connector 30 arranged at the end of the signal transmission bus 1 does not need to be bent.

As shown in FIGS. 1 to 3, in the illustrated embodiment, the electrical connection assembly 3 also includes a second connection terminal 32 and a welding terminal 33. One end of the second connection terminal 32 is crimped to the electrical connector 30, the other end is crimped to a connection end of the welding terminal 33, and the welding terminal 33 is welded to the bus bar 2. In this way, the electrical connection between the electrical connector 30 and the bus bar 2 can be realized.

As shown in FIGS. 1 to 3, in the illustrated embodiment, toothed wings 32a are respectively formed on both sides of one end of the second connection terminal 32, which are crimped to the electrical connector 30 by puncture crimping. The toothed wings 32a on both sides of the second connection terminal 32 are staggered by a predetermined distance in the extension direction of the second connection terminal 32, that is, the toothed wings 32a on one side of the second connection terminal 32 are staggered from the toothed wings 32a on the other side of the second connection terminal 32. In this way, the toothed wings 32a on both sides are staggered from each other after being crimped to the electrical connector 30, which may improve the electrical connection performance between the second connection terminal 32 and the electrical connector 30.

As shown in FIGS. 1 to 3, in the illustrated embodiment, a pair of side wings 32b are formed at the other end of the second connection terminal 32, and a pair of side wings 32b are symmetrically arranged on both sides of the other end of the second connection terminal 32 and crimped to the connection end of the welding terminal 33.

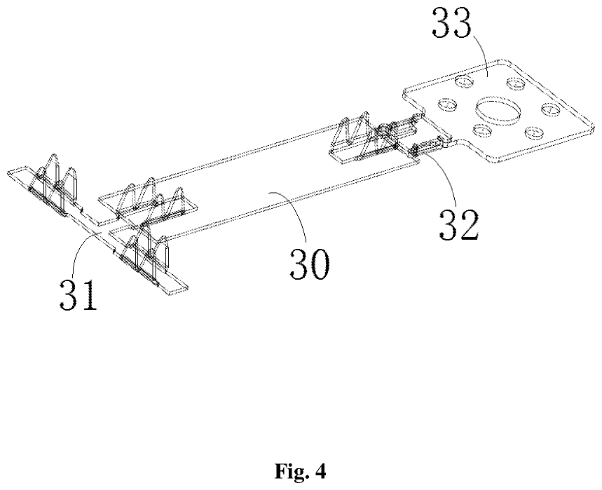

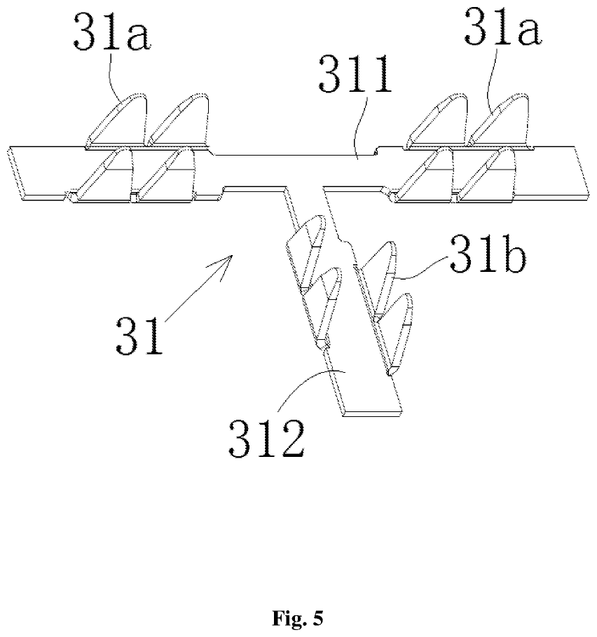

FIG. 4 shows an illustrative view of an electrical connection assembly 3 of a battery pack signal acquisition device according to another exemplary embodiment of the present invention; FIG. 5 shows an illustrative perspective view of a first connection terminal 31 of the electrical connection assembly 3 shown in FIG. 4.

The main difference between the embodiments shown in FIGS. 4-5 and the embodiments shown in FIGS. 1-3 is that the structure of the first connection terminal 31 is different.

As shown in FIGS. 4 to 5, in the illustrated embodiment, the first connection terminal 31 includes a first body 311 extending a first length in a first direction and a second body 312 extending a second length in a second direction. One end of the second body 312 is vertically connected to the middle part of the first body 311 so that the first connection terminal 31 is T-shaped.

As shown in FIGS. 4 to 5, in the illustrated embodiment, first wings 31a are formed on both sides of each end of the first body 311, and the first wings 31a are toothed, so that they can be crimped to the signal transmission bus 1 by puncture crimping.

As shown in FIGS. 4 to 5, in the illustrated embodiment, second wings 31b are respectively formed on both sides of the other end of the second body 312, and the second wings 31b are toothed, so that they can be crimped to the electrical connector 30 by puncture crimping.

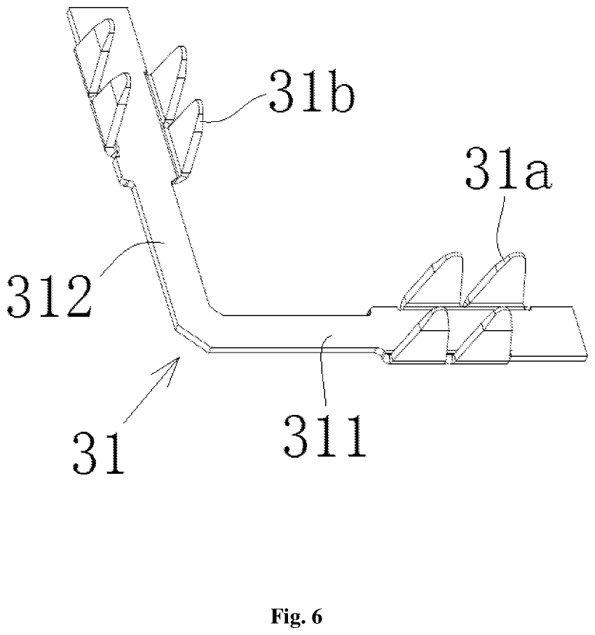

However, please note that the structure of the first connection terminal 31 of the present invention is not limited to the illustrated embodiment, but may also have other structures. For example, FIG. 6 shows an illustrative perspective view of a first connection terminal according to another exemplary embodiment of the present invention. As shown in FIG. 6, the first connection terminal 31 includes a first body 311 extending a first length in a first direction and a second body 312 extending a second length in a second direction. One end of the second body 312 is vertically connected to one end of the first body 311, so that the first connection terminal 31 is L-shaped. First wings 31a are respectively formed on both sides of the other end of the first body 311, and the first wings 31a are toothed, so that they can be crimped to the signal transmission bus 1 by puncture crimping. A second wings 31b are formed on both sides of the other end of the second body 312, and the second wings 31b are toothed, so that they can be crimped to the electrical connector 30 by puncture crimping.

As shown in FIGS. 4 to 5, in the illustrated embodiment, the first wings 31a on both sides of each end of the first body 311 are staggered by a predetermined distance in the extension direction of the first body 311, so that the first wings 31a on both sides of each end of the first body 311 are staggered from each other after crimping to the signal transmission bus 1, which can improve the electrical connection performance between the first connection terminal 31 and the signal transmission bus 1.

As shown in FIGS. 4 to 5, in the illustrated embodiment, the second wings 31b on both sides of the other end of the second body 312 are staggered by a predetermined distance in the extension direction of the second body 312, so that the second wings 31b on both sides are staggered from each other after being crimped to the electrical connector 30, which can improve the electrical connection performance between the first connection terminal 31 and the electrical connector 30.

As shown in FIGS. 4 to 5, in the illustrated embodiment, since the first connection terminal 31 is T-shaped, the electrical connector 30 arranged on the side of the signal transmission bus 1 does not need to be bent, so that the electrical connection performance between the electrical connector 30 and the signal transmission bus 1 can be improved.

Except for the above differences, other technical features of the embodiments shown in FIGS. 4-5 are basically the same as those shown in FIGS. 1-3, and the other technical features may refer to the embodiments shown in FIGS. 1-3 and will not be repeated here.

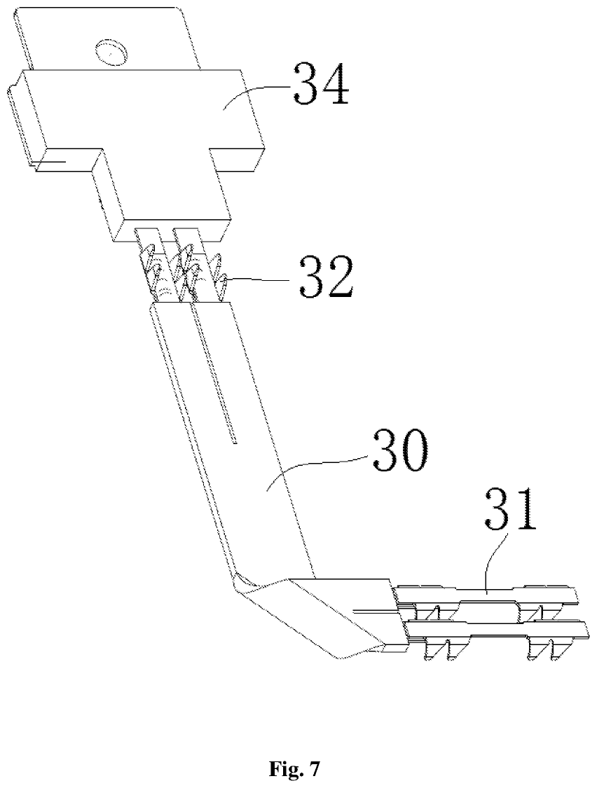

FIG. 7 shows an illustrative view of an electrical connection assembly according to another exemplary embodiment of the present invention.

In another exemplary embodiment of the present invention, as shown in FIG. 7, the aforementioned electrical connection assembly 3 may also include a temperature sensor assembly 34 for detecting the temperature of the bus bar 2, and the temperature sensor assembly 34 is electrically connected with the second connection terminal 32.

Although not shown, in another exemplary embodiment of the present invention, the battery pack signal acquisition device may also include a bracket. The signal transmission bus 1 and the electrical connection assembly 3 can be installed on the bracket respectively.

As shown in FIGS. 1 to 5, in an exemplary embodiment of the present invention, an electrical connection assembly 3 is also disclosed, which is used to electrically connect the bus bar 2 to the signal transmission bus 1 to collect the electrical parameters of the battery cell.

As shown in FIGS. 1 to 5, in the illustrated embodiment, the electrical connection assembly 3 includes an electrical connector 30 and a first connection terminal 31. One end of the first connection terminal 31 is electrically connected with the electrical connector 30. The other end of the first connection terminal 31 is crimped to the signal transmission bus 1 to electrically connect the electrical connection assembly 3 to the signal transmission bus 1. In an exemplary embodiment of the present invention, the signal transmission bus 1 is a flexible flat cable or a flexible printed circuit, and the first connection terminal 31 is suitable for being crimped to the signal transmission bus 1 by puncture crimping.

As shown in FIGS. 1 to 5, in the illustrated embodiment, the electrical connection assembly 3 also includes a second connection terminal 32, one end of the second connection terminal 32 is crimped to the electrical connector 30, and the other end is electrically connected to the bus bar 2 to collect the electrical signal of the battery cell.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A battery pack signal acquisition device, comprising:
a signal transmission bus; and
an electrical connection assembly for electrically connecting a battery cell to the signal transmission bus to collect an electrical parameter of the battery cell,
wherein the electrical connection assembly and the signal transmission bus are respectively formed and electrically connected with each other.

2. The battery pack signal acquisition device according to claim 1, further comprising:
an electrical adapter electrically connected with the electrical connection assembly and the signal transmission bus respectively.

3. The battery pack signal acquisition device according to claim 2,
wherein the electrical adapter comprises a pair of connection terminals adapted to mated with each other, the pair of connection terminals are electrically connected with the electrical connection assembly and the signal transmission bus respectively, so that the electrical connection assembly and the signal transmission bus are detachably connected.

4. The battery pack signal acquisition device according to claim 2,
wherein the electrical adapter includes a first connection terminal which is crimped to the signal transmission bus to electrically connect the electrical connection assembly to the signal transmission bus.

5. The battery pack signal acquisition device according to claim 4,
wherein the first connection terminal is crimped to the signal transmission bus by puncture crimping.

6. The battery pack signal acquisition device according to claim 5,
wherein the first connection terminal is crimped to the electrical connection assembly by puncture crimping to realize an electrical connection between the first connection terminal and the electrical connection assembly.

7. The battery pack signal acquisition device according to claim 6,
wherein the first connection terminal comprises a body extending along a straight line, a first wing is formed on each side of one end of the body, and a second wing is formed on each side of the other end of the body;
wherein the first wing and the second wing are symmetrically arranged at both ends of the body, so that the first wing and the second wing are interchangeable in use without distinction.

8. The battery pack signal acquisition device according to claim 4,
wherein the first connection terminal comprises a first body and a second body, one end of the second body is vertically connected to the middle part of the first body, so that the first connection terminal is in a T-shape.

9. The battery pack signal acquisition device according to claim 4,
wherein the first connection terminal comprises a first body and a second body, one end of the second body is vertically connected to one end of the first body, so that the first connection terminal is in an L-shape.

10. The battery pack signal acquisition device according to claim 1,
wherein the electrical connection assembly further includes an electrical connector, one end of the electrical connector is electrically connected with the signal transmission bus, and the other end is electrically connected to the battery cell.

11. The battery pack signal acquisition device according to claim 10,
wherein the electrical connector is a flexible electrical connector and comprises a flexible film carrier and a conductive trace integrated on the flexible film carrier.

12. The battery pack signal acquisition device according to claim 11,
wherein the electrical connector further includes a fuse integrated on the flexible film carrier and electrically connected with the conductive trace.

13. The battery pack signal acquisition device according to claim 12,
wherein the fuse includes a surface mount fuse adapted to be mounted on the flexible film carrier in a surface mount manner and/or a conductive trace fuse formed on the flexible film carrier in the form of a conductive trace.

14. The battery pack signal acquisition device according to claim 10,
wherein the electrical connector is a flexible flat cable, a flexible printed circuit board or a flexible wire.

15. The battery pack signal acquisition device according to claim 10,
wherein the battery pack signal acquisition device comprises a plurality of electrical connectors arranged at an end and a side of the signal transmission bus, the electrical connector arranged at the side of the signal transmission bus is bent in a non-linear shape, and the electrical connector arranged at the end of the signal transmission bus is not bent.

16. The battery pack signal acquisition device according to claim 10,
wherein the electrical connection assembly further includes a second connection terminal, one end of the second connection terminal is connected to the electrical connector, and the other end is electrically connected to the battery cell.

17. The battery pack signal acquisition device according to claim 16,
wherein the electrical connection assembly further includes a welding terminal to be welded to the battery cell, and the other end of the second connection terminal is connected with the welding terminal.

18. The battery pack signal acquisition device according to claim 16,
wherein the electrical connection assembly further includes a temperature sensor assembly for detecting the temperature of the battery cell, and the temperature sensor assembly is electrically connected with the second connection terminal.

19. The battery pack signal acquisition device according to claim 1, further comprising:
a bracket on which the signal transmission bus and the electrical connection assembly are installed.

20. An electrical connection assembly for electrically connecting a battery cell to a signal transmission bus,
wherein the electrical connection assembly comprises an electrical connector, a first connection terminal and a second connection terminal;
wherein one end of the first connection terminal is electrically connected with the electrical connector, the other end of the first connection terminal is adapted to be connected to a signal transmission bus to electrically connect the electrical connection assembly to the signal transmission bus;
wherein one end of the second connection terminal is connected to the electrical connector, and the other end is electrically connected to a battery cell to collect an electrical signal of the battery cell.
